(19) United States
(12) Patent Application Publication
(10) Pub. No.: US 2008/0020582 A1
(43) Pub. Date: Jan. 24, 2008

(54) Method of forming an opening in a semiconductor device and method of manufacturing a semiconductor device using the same

(76) Inventor: Keun-Hee Bai, Suwon-si (KR)

Correspondence Address: HARNESS, DICKEY & PIERCE, P.L.C., P.O. BOX 8910, RESTON, VA, 20195, US

(21) Appl. No.: 11/822,058

(22) Filed: Jul. 2, 2007

(30) Foreign Application Priority Data
Jun. 30, 2006 (KR) 10-2006-0060273

(51) Int. Cl. H01L 21/467

(52) U.S. Cl. 438/714; 257/E21.486

(57) ABSTRACT

In methods of forming an opening in a semiconductor device and methods of manufacturing a semiconductor device, a mask pattern may be formed on a layer to selectively expose the layer through the mask pattern. The layer may be partially etched using the mask pattern as an etching mask and using a first etching gas including carbon under a silicon-containing gas atmosphere until a lower layer beneath the layer is exposed to form a preliminary opening. The layer may be etched using the mask pattern as an etching mask and using a second etching gas until the lower layer is exposed to form an opening through the layer. The layer may be an insulation layer.

### PRIORITY STATEMENT

This application claims priority under 35 USC § 119 to Korean Patent Application No. 2006-60273, filed on Jun. 30, 2006, in the Korean Intellectual Property Office (KIPO), the entire contents of which are herein incorporated by reference.

### BACKGROUND

1. Field

Example embodiments relate to methods of forming an opening in a semiconductor device and methods of manufacturing a semiconductor device using the same. Other example embodiments relate to methods of forming an opening, e.g., a hole or a recess, in a semiconductor device during a process for manufacturing a semiconductor device and methods of manufacturing the semiconductor device using the methods of forming an opening.

2. Description of the Related Art

As an integration degree of a semiconductor device has been increased in proportion to a decrease in a design rule, a size of a contact plug connected between unit devices has also decreased. Accordingly, a width and a depth of a contact hole for forming the contact plug have been narrowed and deepened. Generally, an insulation layer on a substrate may be etched using an etching gas under conditions where a relatively high bias voltage is applied to form the contact hole. Ions of the etching gas may collide with a sidewall of the contact hole or a mask pattern on the insulation layer, and may then be scattered in all directions. While the sidewall of the contact hole is etched by the ions, a bowing effect (where a middle portion of the contact hole becomes wider) may be caused. Due to the bowing effect, a middle width of the contact hole may be greater than an inlet width of the contact hole. When the bowing effect is generated in an increased scale, adjacent contact holes may be connected to each other.

In one conventional method of preventing or reducing the bowing effect from occurring, after a preliminary contact hole is formed using a first etching gas, the preliminary contact hole may be etched using a second etching gas having an etching selectivity higher than that of the first etching gas to form a contact hole. However, the bowing effect may not be prevented or retarded. Further, a margin for preventing or retarding the closing of the contact hole may be reduced.

In another conventional method of preventing or retarding the bowing effect from occurring, after a contact hole is partially formed, a spacer may be formed on a sidewall of the contact hole where the bowing effect occurs. However, the above-mentioned conventional method may have disadvantages such that not only the margin may be gradually reduced but also additional processes for forming the spacer may be needed.

### SUMMARY

Example embodiments provide methods of forming an opening in a semiconductor device that is capable of preventing or retarding a bowing effect. Example embodiments provide methods of manufacturing a semiconductor device using the above-mentioned methods.

In a method of forming an opening in a semiconductor device in accordance with example embodiments the present invention, a mask pattern may be formed on a layer on a substrate to selectively expose the layer through the mask pattern. The layer may be partially etched using the mask pattern as an etching mask and using a first etching gas including carbon under a silicon-containing gas atmosphere until a lower layer beneath the layer is exposed to form a preliminary opening. The layer may be etched using the mask pattern as an etching mask and using a second gas until the lower layer is exposed to form an opening through the layer. According to example embodiments, the layer may be an insulation layer.

According to example embodiments, a protection layer may be formed on a sidewall of the preliminary opening to prevent or reduce etching of the sidewall of the preliminary opening when the preliminary opening is formed. The protection layer may include a polymer having silicon. The protection layer may be removed after forming the opening.

According to example embodiments, the silicon-containing gas may include tetrafluorosilane (SiF₄), difluorosilane (SiH₂F₂), silyl fluoride (SiH₃F), hexafluorodisilane (Si₂F₆), tetrachlorosilane (SiCl₄), trichlorosilane (SiHCl₃), dichlorosilane (SiH₂Cl₂), monochlorosilane (SiH₃Cl), hexachlorodisilane (Si₂Cl₆) and/or silane (SiH₄). These may be used alone or in a mixture thereof.

According to example embodiments, the first etching gas and the second etching gas may include chlorine or fluorine, respectively. According to example embodiments, the first etching gas may be substantially the same as the second etching gas. Alternatively, the second etching gas may have a substantially higher etching ratio with respect to the insulation layer than that of the first etching gas.

According to example embodiments, an oxygen gas and an inactive gas may be further applied to the substrate to control etching ratios of the first etching gas and the second etching gas when the preliminary opening and the opening are formed, respectively. The first etching gas, the second etching gas, the oxygen gas and the inactive gas may be provided in a plasma state. According to example embodiments, the opening may have an aspect ratio of more than about 5.

In a method of forming an opening in a semiconductor device in accordance with example embodiments of the present invention, a layer on a substrate may be partially etched to form a preliminary opening having a protection layer that is formed on a sidewall of the preliminary opening. A bottom surface of the preliminary opening may then be etched to form an opening through which a lower layer beneath the layer is exposed. According to example embodiments, the layer may be an insulation layer.

According to example embodiments, the protection layer may include a polymer having silicon. According to example embodiments, the protection layer may be removed from the opening after forming the opening. According to example embodiments, the preliminary opening may be formed using a first etching gas under a silicon-containing gas atmosphere. Further, the opening may be formed using a second etching gas. The silicon-containing gas may include tetrafluorosilane (SiF₄), difluorosilane (SiH₂F₂), silyl fluoride (SiH₃F), hexafluorodisilane (Si₂F₆), tetrachlorosilane (SiCl₄), trichlorosilane (SiHCl₃), dichlorosilane (SiH₂Cl₂), monochlorosilane (SiH₃Cl), hexachlorodisilane (Si₂Cl₆) and/or silane (SiH₄). These may be used alone or in a mixture thereof. The first etching gas and the second etching gas may include chlorine or fluorine, respectively. The first etching gas may be substantially the same as the second etching gas.

Alternatively, the second etching gas may have an etching ratio with respect to the insulation layer substantially higher than that of the first etching gas. Additionally, an oxygen gas and an inactive gas may be further applied to the substrate to control etching ratios of the first etching gas and the second etching gas when the preliminary opening and the opening are formed, respectively. The first etching gas, the second etching gas, the oxygen gas and the inactive gas may be provided in plasma state. According to example embodiments, the opening may have an aspect ratio of more than about 5.

In a method of manufacturing a semiconductor device in accordance with example embodiments of the present invention, a layer may be formed on a semiconductor substrate where an insulation layer having a contact plug is formed. Either of the methods of forming an opening according to example embodiments may be performed. A conductive layer may be formed continuously on a sidewall and a bottom face of the opening, and an upper surface of the layer. The conductive layer may be selectively etched to form a lower electrode. A dielectric layer and an upper electrode may be successively formed on the lower electrode. According to example embodiments, the layer may be a mold layer and the lower layer may be a contact plug.

According to example embodiments, when the opening having a relatively large aspect ratio is formed, the polymer including silicon may be formed on the sidewall of the opening such that the bowing effect may not be generated. Further, a line width of a lower portion of the opening may be sufficiently increased.

### BRIEF DESCRIPTION OF THE DRAWINGS

Example embodiments will be more clearly understood from the following detailed description taken in conjunction with the accompanying drawings. FIGS. 1A-2H represent non-limiting, example embodiments as described herein.

FIGS. 1A to 1D are cross-sectional views illustrating a method of forming an opening in a semiconductor device in accordance with example embodiments; and

FIGS. 2A to 2H are cross-sectional views illustrating a method of manufacturing a semiconductor device in accordance with example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments are described more fully hereinafter with reference to the accompanying drawings, in which example embodiments are shown. Example embodiments may, however, be embodied in many different forms and should not be construed as limited to the example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

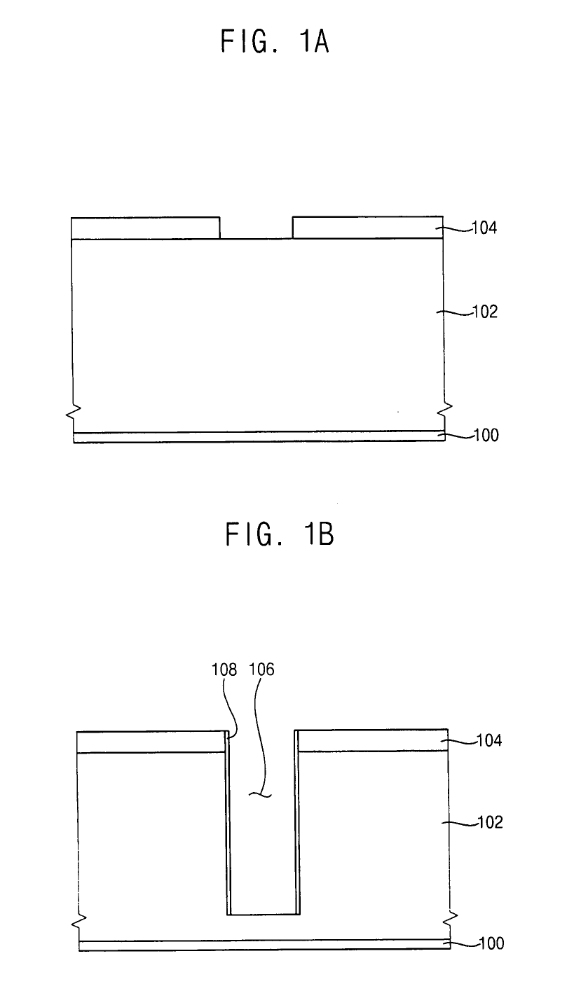

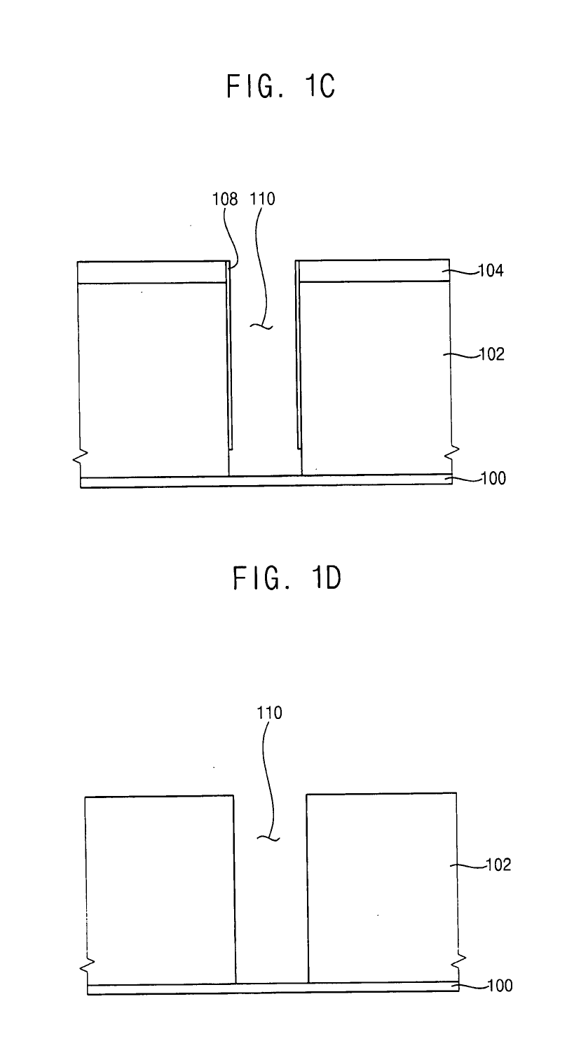

FIGS. 1A to 1D are cross-sectional views illustrating a method of forming an opening in a semiconductor device in accordance with example embodiments. Referring to FIG. 1A, an insulation layer 102 may be formed on a semiconductor substrate 100. In example embodiments, the insulation layer may be formed using an oxide, e.g., boro-phosphor-silicate glass (BPSG), phosphor-silicate glass (PSG), spin-on-glass (SOG), plasma-enhanced tetraethylorthosilicate (PE-TEOS) and/or high density plasma chemical vapor deposition (HDP-CVD). The insulation layer 102 may be formed by performing a low pressure chemical vapor process (LPCVD) process, a plasma-enhanced chemical vapor deposition (PECVD) process and/or by performing a planarization process.

A mask pattern 104 may be formed on the insulation layer 102 having a planarized upper surface to selectively expose the insulation layer 102 through the mask pattern 104. In example embodiments, the mask pattern may include tungsten, photoresist, polysilicon and/or silicon nitride.

Referring to FIG. 1B, a silicon-containing gas, a first etching gas, an oxygen gas and an inactive gas may be applied to the semiconductor substrate 100. In example embodiments, the silicon-containing gas may include tetrafluorosilane (SiF₄), difluorosilane (SiH₂F₂), silyl fluoride (SiH₃F), hexafluorodisilane (Si₂F₆), tetrachlorosilane (SiCl₄), trichlorosilane (SiHCl₃), dichlorosilane (SiH₂Cl₂), monochlorosilane (SiH₃Cl), hexachlorodisilane (Si₂Cl₆) and/or silane (SiH₄). These may be used alone or in a mixture thereof. For example, the silane (SiH₄) may be used as the silicon-containing gas.

Further, the first etching gas may include a gas having carbon (C) and chlorine (Cl) and/or a gas having carbon (C) and fluorine (F). For example, the gas having carbon and fluorine may include hydrofluorocarbon (CₓH_{y}F_{z}) gas. Furthermore, the inactive gas may include a hydrogen gas, a helium gas, an argon gas and/or a nitrogen gas. For example, an argon gas may be used as the inactive gas.

The silicon-containing gas, the first etching gas, the oxygen gas and the inactive gas may be provided in a plasma state. The gases may be dissociated in the plasma state to be converted into a radical state or an ion state. For example, the silicon-containing gas, e.g., SiF₄, may be dissociated to form a silicon ion and a fluorine ion. The first etching gas, e.g., the hydrofluorocarbon gas, may be dissociated to form carbon fluoride (CFₓ). The oxygen gas may be dissociated to form an oxygen radical. The inactive gas may be dissociated to form an argon ion. The radical or ions may be accelerated into the substrate 100 by a bias voltage.

The first etching gas in the plasma state may be reacted with the insulation layer 102 to etch the insulation layer 102. For example, carbon fluoride (CFₓ) may be absorbed on the exposed insulation layer 102 to form a polymer layer (not shown). The insulation layer 102 and the polymer layer may be reacted with each other by ion energy of the inactive gas, thereby etching the insulation layer 102. The oxygen radical and the fluorine ion, which is dissociated from the hydrofluorocarbon gas, may be reacted with carbon fluoride (CFₓ) to reduce a thickness of the carbon fluoride (CFₓ) polymer layer. When the carbon fluoride (CFₓ) polymer layer is relatively thin, the insulation layer 102 may be easily etched.

The insulation layer 102 may be etched to form a preliminary opening 106. The process of etching the insulation layer 102 may be stopped before a lower portion of the insulation layer 102 is exposed. For example, a depth of the preliminary opening 106 may range from about 60% to about 95% of the thickness of the insulation layer 102.

The silicon ions of the silicon source gas may be absorbed on a sidewall of the preliminary opening 106 to form a protection layer 108. In example embodiments, the protection layer 108 may include a polymer having silicon. For example, a polymer including silicon may be silicon carbide (SiC). Because a relatively large number of ions may collide with a surface of the mask pattern 104 and a bottom surface of the preliminary opening 106 due to the bias voltage, the protection layer 108 may not be formed on the surface of the mask pattern 104 and the bottom surface of the preliminary opening 106. On the other hand, because a relatively small number of ions may collide with the sidewall of the preliminary opening 106, the protection layer 108 may be formed on the sidewalls of the preliminary opening 106.

The protection layer 108 may prevent or retard etching of the sidewall of the preliminary opening 106 by the first etching gas. Thus, the bowing effect, which is caused by etching the sidewalls of the preliminary opening 106, may not be generated.

In the above-mentioned etching process using the silicon source gas, when the insulation layer 102 is etched until the lower portion of the insulation layer 102 is exposed, the preliminary opening 106 may have a sloping profile due to the effect of the protection layer 108 on the sidewalls of the preliminary opening 106. Thus, a line width of the bottom surface of the preliminary opening 106 may be reduced.

Referring to FIG. 1C, a second etching gas, an oxygen gas and an inactive gas (not including a silicon source gas) may be applied to the semiconductor substrate 100 having the preliminary opening 106. For example, the second etching gas may include a gas containing carbon and chlorine (Cl) and/or a gas containing carbon and fluorine (F). The gas containing carbon and fluorine may include hydrofluorocarbon (CₓH_{y}F_{z}) gas. Alternatively, the second etching gas may include a gas containing chlorine without carbon or a gas containing fluorine without carbon.

Accordingly, the second etching gas may be substantially the same as the first etching gas. On the other hand, the second etching gas may be different from the first etching gas. For example, the second etching gas may have an etching ratio with respect to the insulation layer higher than the first etching gas. The inactive gas may include a hydrogen gas, a helium gas, an argon gas and/or a nitrogen gas. For example, an argon gas may be used as the inactive gas.

The second etching gas, the oxygen gas and the inactive gas may be provided in a plasma state. The gases may be dissociated in the plasma state to be converted into a radical state or an ion state. For example, the silicon-containing gas, e.g., SiF₄, may be dissociated to generate a silicon ion and a fluorine ion. The second etching gas, e.g., the hydrofluorocarbon gas, may be dissociated to generate carbon fluoride (CFₓ). The oxygen gas may be dissociated to generate an oxygen radical. The inactive gas may be dissociated to form an argon ion. The radical or ions may be accelerated into the substrate 100 by a bias voltage.

The second etching gas in the plasma state may be reacted with the insulation layer 102 to etch the bottom surface of the preliminary opening 106. For example, carbon fluoride (CFₓ) may be absorbed on the exposed insulation layer 102 to form a polymer layer (not illustrated). The insulation layer 102 and the polymer layer may react with each other by ion energy of the inactive gas, so that the insulation layer 102 may be etched. The oxygen radical and the fluorine ion, which is dissociated from the hydrofluorocarbon gas, may be reacted with carbon fluoride (CFₓ) to reduce a thickness of the carbon fluoride (CFₓ) polymer layer. When the carbon fluoride (CFₓ) polymer layer is relatively thin, the insulation layer 102 may be more easily etched.

The insulation layer 102 may be etched until the bottom surface of the insulation layer 102 is completely exposed to form an opening 110 through the insulation layer 102. Because the silicon-containing gas is not applied to the substrate 100 when etching the insulation layer 102, the protection layer 108 may no longer be formed on the sidewall of the opening 110. Further, because the protection layer 108 is not formed on the sidewall of a lower portion of the opening 110, the sidewall of the lower portion of the opening 110 may be etched. Therefore, a line width of the bottom surface of the opening 110 may be sufficiently secured.

The above-mentioned method of forming the opening may be used when an aspect ratio of the opening 110 is more than about 5. When the aspect ratio of the opening 110 is less than about 5, the bowing effect and a narrow line width may not occur regardless of using the method of example embodiments. The aspect ratio of more than about 5 means that a ratio of the height to the width may be about 1:5 or greater than about 1:5. Referring to FIG. 1D, after the mask pattern 104 is removed from the substrate 100, the protection layer 108 and by-products may be removed from the substrate 100 by a cleaning process.

Accordingly, the above-mentioned method of forming the opening according to example embodiments may prevent or reduce the bowing effect although the opening 110 has a relatively large aspect ratio. Additionally, the lower portion of the opening 110 may have a sufficiently wide line width.

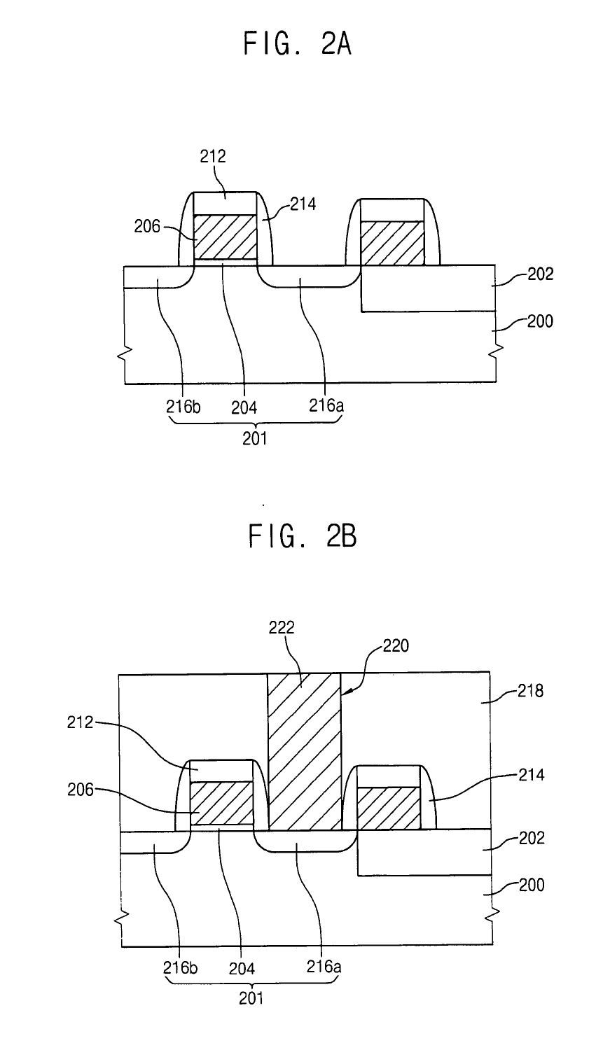

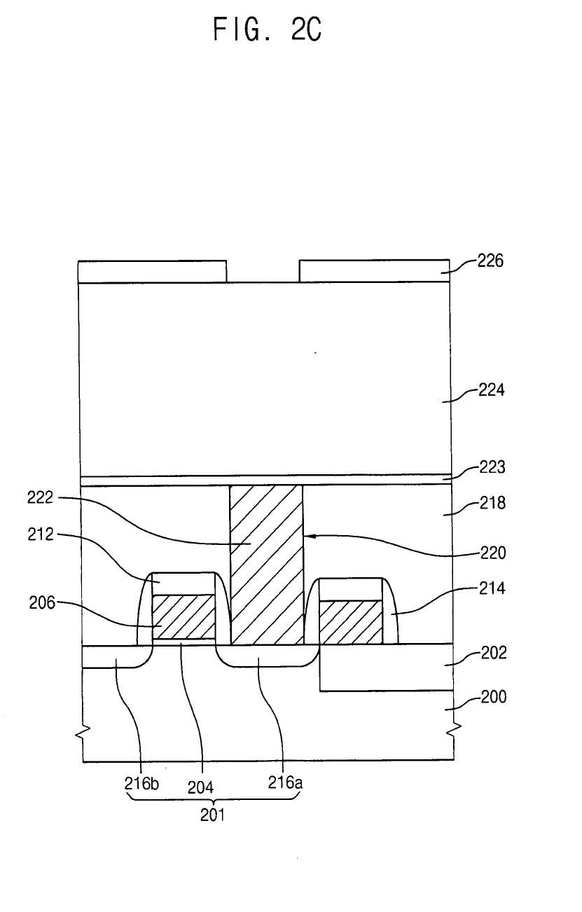

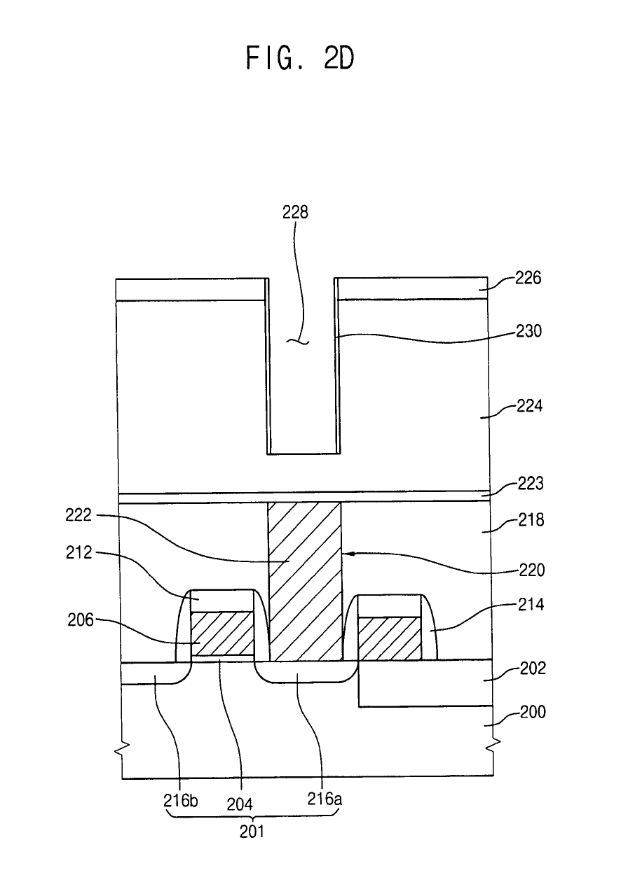

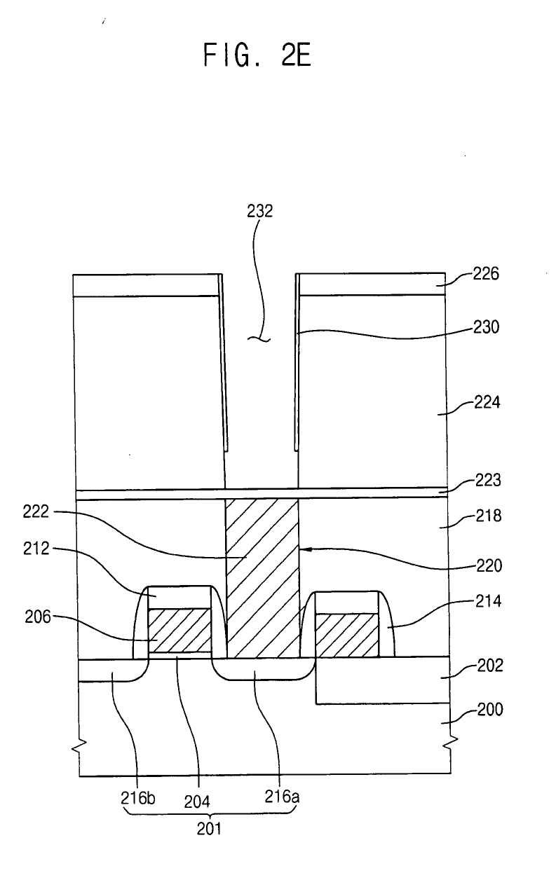

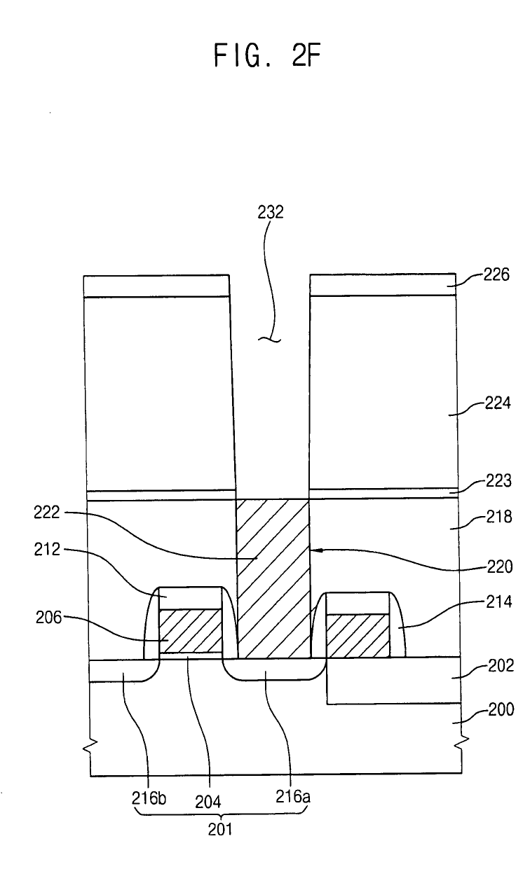

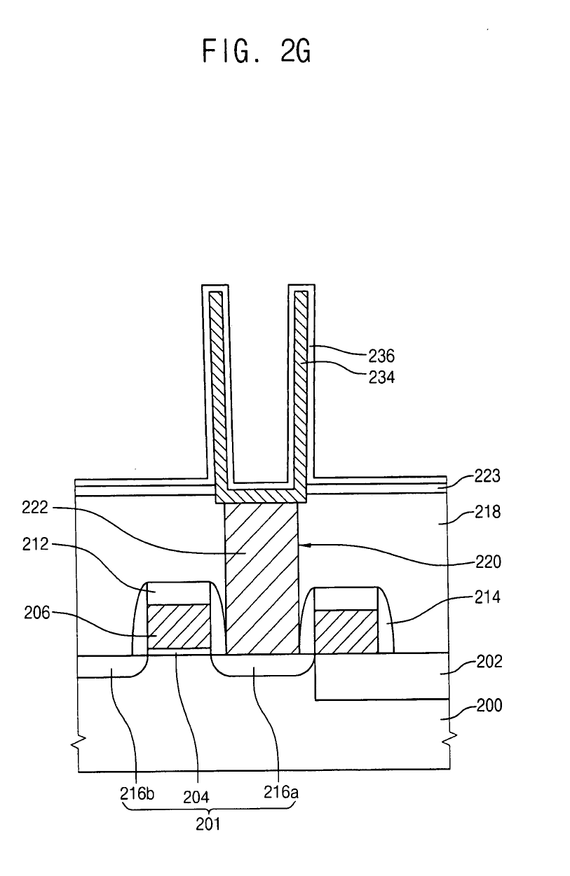

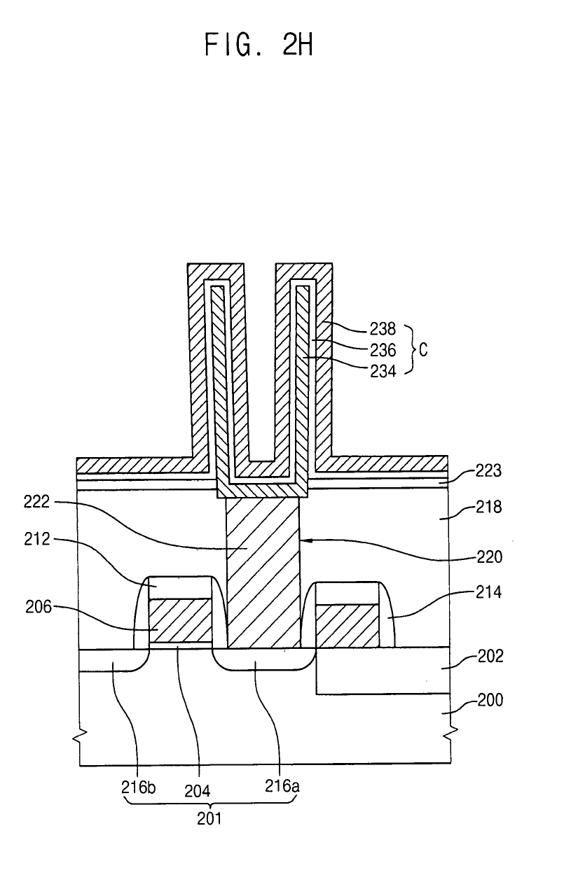

FIGS. 2A to 2H are cross-sectional views illustrating a method of manufacturing a semiconductor device in accordance with example embodiments. Referring to FIG. 2A, an isolation layer 202 including an oxide may be formed on the semiconductor substrate 200. For example, the isolation layer 202 may be formed by an isolation process, e.g., a shallow trench isolation (STI) process, a thermal oxidation process and/or a local oxidation of silicon (LOCOS) process. The isolation layer 202 may define an active region 201 and a field region (not illustrated) on the semiconductor device 200.

A relatively thin gate oxide layer (not illustrated) may be formed on the semiconductor substrate 200 including the isolation layer 202. For example, the gate oxide layer may be formed by a thermal oxidation process and/or a chemical vapor deposition (CVD) process. The gate oxide layer may be formed only in the active region 201 on the semiconductor substrate 200. The gate oxide layer may be patterned to form a gate oxide layer pattern 204.

A first conductive layer (not illustrated) and a first mask layer (not illustrated) may be sequentially formed on the gate oxide layer. The first conductive layer and the first mask layer correspond to a gate conductive layer and a gate mask layer, respectively. The first conductive layer may be patterned to form a gate conductive layer pattern 206. In example embodiments, the first conductive layer may include polysilicon doped with impurities. Alternatively, the first conductive layer may have a polycide structure including polysilicon doped with impurities and metal silicide.

The first mask layer may be patterned to form a gate mask 212. The first mask layer may be formed using a material having an etch selectivity with respect to an insulation layer 218 (see FIG. 2B) that is sequentially formed on the first mask layer. For example, when the insulation layer 218 includes oxide, e.g., silicon oxide, the first mask layer may be formed using nitride, e.g., silicon nitride.

After a first photoresist pattern (not illustrated) is formed on the first mask layer, the first mask layer, the first conductive layer and the gate oxide layer may be etched using the first photoresist pattern as an etching mask to form a gate structure on the semiconductor substrate 200. The gate structure may include the gate oxide layer pattern 204, the gate conductive layer pattern 206 and the gate mask 212. For example, the first mask layer, the first conductive layer and the gate oxide layer may be etched using the first photoresist pattern as an etching mask to form a gate structure including the gate oxide layer pattern 204, the gate conductive layer pattern 206 and the gate mask 212 on the semiconductor substrate 200. Then, the first photoresist pattern may be removed from the gate mask 212 by an ashing process and/or a stripping process.

An insulation layer (not illustrated) including nitride, e.g., silicon nitride, may be formed on the semiconductor substrate 200 to cover the gate structures. The insulation layer may then be anisotropically etched to form a gate spacer 214 on a sidewall of each gate structure. Impurities may be implanted into a portion of the substrate that is exposed between the gate structures using the gate structures as an ion implantation mask to form contact regions 216a and 216b corresponding to source/drain regions in the semiconductor substrate 200 by a thermal process. Thus, a metal oxide semiconductor (MOS) transistor structure may be formed on the semiconductor substrate 200. The gate structures in the active region 201 of the semiconductor device 200 may be electrically separated from adjacent gate structures by the gate spacers 214 formed on the sidewalls of the gate structures.

Referring to FIG. 2B, the insulation layer 218 may be formed on the semiconductor substrate 200 to cover the gate structures. For example, the insulation layer may be formed using oxide, e.g., BPSG, PSG, SOG, PE-TEOS and/or HDP-CVD. An upper surface of the insulation layer 218 may be planarized by a planarizing process. The planarizing process may include a chemical mechanical polishing (CMP) process and/or an etch-back process. These may be used in a combination thereof.

A second photoresist pattern (not illustrated) may be formed on the planarized insulation layer 218. The insulation layer 218 may be anisotropically etched using the second photoresist pattern as an etching mask to form a first contact hole 220 that exposes the contact region 216a. For example, when the insulation layer includes oxide, the insulation layer 218 may be etched using an etching gas having an increased etch selectivity with respect to the gate mask 212 including nitride. Thus, the contact region 216a may be exposed through the first contact hole 220.

The second photoresist pattern may be removed from the insulation layer 218 by an ashing process and/or a stripping process. A second conductive layer (not illustrated) may be formed on the insulation layer 218 to fill the first contact hole 220. In example embodiments, the second conductive layer may be formed using polysilicon doped with impurities. Alternatively, the second conductive layer may be formed using a metal, e.g., tungsten, aluminum and/or copper and/or a metal nitride, for example, titanium nitride. The second conductive layer may be etched until an upper surface of the planarized insulation layer 218 is exposed to form a contact plug 222 in the first contact hole 220. For example, the second conductive layer may be etched by a CMP process, an etch-back process and/or a combination thereof.

Referring to FIG. 2C, an etch stop layer 223 may be formed on the insulation layer 218 including the contact plug 222. The etch stop layer 223 may be formed using a material having an etch selectivity with respect to the insulation layer 218 including oxide and a mold layer 224. For example, the etch stop layer 223 may be formed using nitride, e.g., silicon nitride.

The mold layer 224 for forming a lower electrode (not illustrated) may be formed on the etch stop layer 223. The mold layer 224 may be formed using an oxide, e.g., BPSG, PSG, USG, TEOS, SOG and/or HDP-CVD. A thickness of the mold layer 224 may properly vary in accordance with a capacitance required in a capacitor. For example, because a height of the capacitor may depend on the thickness of the mold layer 224, the thickness of the mold layer 224 may be properly controlled in order to form a capacitor having a required capacitance.

Referring again to FIG. 2C, a second mask layer (not illustrated) may be formed on the mold layer 224. The second mask layer may be formed using a material having an etch selectivity with respect to the mold layer 224. For example, the second mask layer may be formed using polysilicon and/or silicon nitride.

After a third photoresist pattern (not illustrated) is formed on the second mask layer, the second mask layer may be etched using the third photoresist pattern as an etching mask to form a mask pattern 226 that defines a region where a second contact hole (not illustrated) for the lower electrode is to be formed.

FIGS. 2D to 2E are cross-sectional views illustrating processes for forming a second contact hole. Referring to FIG. 2D, after the third photoresist pattern is removed by an ashing process and/or a stripping process, the mold layer 224 may be partially etched using the mask pattern 226 as an etching mask to form a preliminary contact hole 228. In example embodiments, a silicon-containing gas, a first etching gas, an oxygen gas and an inactive gas may be applied to the substrate 200.

For example, the silicon-containing gas may include tetrafluorosilane (SiF₄), difluorosilane (SiH₂F₂), silyl fluoride (SiH₃F), hexafluorodisilane (Si₂F₆), tetrachlorosilane (SiCl₄), trichlorosilane (SiHCl₃), dichlorosilane (SiH₂Cl₂), monochlorosilane (SiH₃Cl), hexachlorodisilane (Si₂Cl₆) and/or silane (SiH₄). These may be used alone or in a mixture thereof. For example, tetrafluorosilane (SiF₄) may be used as the silicon-containing gas. The first etching gas may include a gas having carbon (C) and chlorine (Cl) and/or a gas having carbon (C) and fluorine (F). For example, the gas having carbon and fluorine may include hydrofluorocarbon (CₓH_{y}F_{z}) gas. The inactive gas may include a hydrogen gas, a helium gas, an argon gas and/or a nitrogen gas. For example, an argon gas may be used as the inactive gas.

The silicon-containing gas, the first etching gas, the oxygen gas and the inactive gas may be provided in a plasma state. The gases may be dissociated in the plasma state to be converted into a radical state or an ion state. For example, the silicon-containing gas, e.g., tetrafluorosilane (SiF₄), may be dissociated to generate a silicon ion and a fluorine ion. The first etching gas, e.g., the hydrofluorocarbon gas, may be dissociated to generate carbon fluoride (CFₓ). The oxygen gas may be dissociated to generate oxygen radical. The inactive gas may be dissociated to form an argon ion. The radical or ions may be accelerated into the substrate 200 by a bias voltage.

The first etching gas in the plasma state may be reacted with the mold layer 224 to etch the mold layer 224. For example, carbon fluoride (CFₓ) may be absorbed on the exposed mold layer 224 to form a polymer layer (not illustrated). The mold layer 224 and the polymer layer may be reacted to each other by induced ion energy of the inactive gas, to etch the mold layer 224. The oxygen radical and the fluorine ion, which is dissociated from the hydrofluorocarbon gas, may be reacted with carbon fluoride (CFₓ) to reduce a thickness of the carbon fluoride (CFₓ) polymer layer. When the carbon fluoride (CFₓ) polymer layer is relatively thin, the mold layer 224 may be more easily etched. The process of etching the mold layer 224 may be stopped before the etch stop layer 223 is exposed. For example, a depth of the preliminary contact hole 228 may range from about 60% to about 95% of the thickness of the mold layer 224.

The silicon ions of the silicon source gas may be absorbed on a sidewall of the preliminary contact hole 228 to form a protection layer 230. The protection layer 230 may include a polymer having silicon. For example, the polymer including silicon may be silicon carbide (SiC). Because a relatively large number of ions may collide with a surface of the mask pattern 226 and a bottom surface of the preliminary contact hole 228 by the bias voltage, the protection layer 230 may not be formed on the surface of the mask pattern 226 and the bottom surface of the preliminary contact hole 228. On the other hand, because a relatively small number of ions may collide with the sidewalls of the preliminary contact hole 228, the protection layer 230 may be formed on the sidewalls of the preliminary contact hole 228.

The protection layer 230 may prevent or retard the sidewall of the preliminary contact hole 228 from being etched by the first etching gas. Thus, the bowing effect, generated when the sidewalls of the preliminary contact hole 228 are etched, may not be generated. In the above-mentioned etching process using the silicon source gas, when the mold layer 224 is etched until the lower portion of the etch stop layer 223 is exposed, the preliminary contact hole 228 may have a sloping profile due to the protection layer 230 formed on the sidewall of the preliminary contact hole 228. Thus, a line width of the bottom surface of the preliminary contact hole 228 may be narrowed.

Referring to FIG. 2E, the preliminary contact hole 228 may be etched until the etch stop layer 223 is exposed to form a second contact hole 232. In example embodiments, a second etching gas, an oxygen gas and an inactive gas may be provided in the semiconductor substrate 200 having the preliminary contact hole 228. For example, the second etching gas may include a gas having carbon (C) and chlorine (Cl) and/or a gas having carbon (C) and fluorine (F). The gas having carbon and fluorine may include hydrofluorocarbon (CₓH_{y}F_{z}) gas. Alternatively, the second etching gas may include a gas having chlorine but not carbon or a gas having fluorine but not carbon.

Accordingly, the second etching gas may be substantially the same as the first etching gas. On the other hand, the second etching gas may be different from the first etching gas. For example, the second etching gas may have an etching ratio with respect to the mold 224 higher than that of the first etching gas. The inactive gas may include a hydrogen gas, a helium gas, an argon gas and/or a nitrogen gas. For example, an argon gas may be used as the inactive gas.

The second etching gas, the oxygen gas and the inactive gas may be provided in plasma state. The gases may be dissociated in the plasma state to be a radical state or an ion state. For example, the silicon-containing gas, e.g., tetrafluorosilane (SiF₄), may be dissociated to generate a silicon ion and a fluorine ion. The second etching gas, e.g., the hydrofluorocarbon gas, may be dissociated to generate carbon fluoride (CFₓ). The oxygen gas may be dissociated to generate oxygen radical. The inactive gas may be dissociated to form an argon ion. The radicals or ions may be accelerated into the substrate 200 by a bias voltage.

The second etching gas in the plasma state may be reacted with the mold layer 224 to etch the bottom surface of the preliminary contact hole 228. For example, carbon fluoride (CFₓ) may be absorbed on the exposed mold layer 224 to form a polymer layer (not illustrated). The mold layer 224 and the polymer layer may be reacted with each other by ion energy of the inactive gas, so that the mold layer 224 may be etched. The oxygen radical and the fluorine ion, which is dissociated from the hydrofluorocarbon gas, may be reacted with carbon fluoride (CFₓ) to reduce a thickness of the carbon fluoride (CFₓ) polymer layer. When the carbon fluoride (CFₓ) polymer layer is relatively thin, the mold layer 224 may be more easily etched.

The mold layer 224 may be etched until the bottom surface of the mold layer 224 may be completely exposed to form the second contact hole 232 in the mold layer 224. Because the silicon-containing gas is not provided to the substrate 200 during etching the mold layer 224, the protection layer 108 may no longer be formed on the sidewalls of the opening 110. Because the protection layer 230 is not formed on the sidewalls of a lower portion of the second contact hole 232, the sidewall of the lower portion of the second contact hole 232 may be etched. Therefore, the bottom surface of the second contact hole 232 may have a sufficiently wide line width.

The above-mentioned method of forming the contact hole may be used when an aspect ratio of the second contact hole 232 is more than about 5. When the aspect ratio of the second contact hole 232 is less than about 5, the bowing effect and a narrow line width may not occur regardless of using the method of example embodiments.

Referring to FIG. 2F, a portion of the etch stop layer 223 where the second contact hole is exposed may be etched using a third etching gas. The third etching gas may have an etch selectivity with respect to the etch stop layer 223 higher than that of the second etching gas. A cleaning process may then be carried out to remove the protection layer 230 and by-products, e.g., a native oxide layer, from the semiconductor substrate 200 having the contact hole 228. For example, the cleaning process may be performed using a cleaning solution including deionized water and ammonia water, or a sulfuric acid solution for about 5 min to about 20 min. Thus, the mold layer 224 may be partially etched to lengthen a diameter of the second contact hole 232.

Referring to FIG. 2G, a third conductive layer (not illustrated) may be formed on inner sidewalls and a bottom face of the second contact hole 232, and an upper face of the mask pattern 226. The third conductive layer may be formed using polysilicon doped with impurities and/or a conductive material, e.g., metal. Then, the third conductive layer on the upper face of the mask pattern 226 and the mold layer 224, except for the third conductive layer on the inner sidewalls and the bottom face of the second contact hole 232, may be removed to form a lower electrode 234. Then, a dielectric layer 236 may then be formed on the lower electrode 235.

Referring to FIG. 2H, an upper electrode 238 may be formed on the dielectric layer 236. Thus, a capacitor (C) including the lower electrode 232, the dielectric layer 236 and the upper electrode 238 may be completed on the semiconductor substrate 200. After an additional insulation layer (not illustrated) for electrically insulating an upper wiring is formed on the capacitor (C), the upper wiring may be formed on the additional insulating layer to complete a semiconductor device.

According to example embodiments, when an opening having a relatively large aspect ratio is formed, a polymer including silicon may be formed on sidewalls of the opening such that the bowing effect may not be generated. Further, a line width of a lower portion of the opening may be sufficiently increased.

The foregoing is illustrative of example embodiments and is not to be construed as limiting thereof. Although a few example embodiments have been described, those skilled in the art will readily appreciate that many modifications are possible in example embodiments without materially departing from the teachings and advantages of example embodiments. Accordingly, all such modifications are intended to be included within the scope of example embodiments as defined in the claims. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A method of forming an opening in a semiconductor device, comprising:
forming a mask pattern on a layer to selectively expose the layer through the mask pattern;
partially etching the layer using the mask pattern as an etching mask and using a first etching gas including carbon under a silicon-containing gas atmosphere until a lower layer beneath the layer is exposed to form a preliminary opening; and
etching the layer using the mask pattern as an etching mask and using a second etching gas until the lower layer is exposed to form an opening through the layer.

2. The method of claim 1, wherein the layer is an insulation layer.

3. The method of claim 1, wherein forming the preliminary opening comprises forming a protection layer on a sidewall of the preliminary opening to reduce etching of the sidewall of the preliminary opening.

4. The method of claim 3, wherein the protection layer includes a polymer including silicon.

5. The method of claim 3, further comprising:
removing the protection layer after forming the opening.

6. The method of claim 1, wherein the silicon-containing gas includes at least one selected from the group consisting of tetrafluorosilane (SiF₄), difluorosilane (SiH₂F₂), silyl fluoride (SiH₃F), hexafluorodisilane (Si₂F₆), tetrachlorosilane (SiCl₄), trichlorosilane (SiHCl₃), dichlorosilane (SiH₂Cl₂), monochlorosilane (SiH₃Cl), hexachlorodisilane (Si₂Cl₆) and silane (SiH₄).

7. The method of claim 1, wherein the first etching gas and the second etching gas include one of chlorine or fluorine.

8. The method of claim 1, wherein the first etching gas is substantially the same as the second etching gas.

9. The method of claim 2, wherein the second etching gas has a higher etching ratio with respect to the insulation layer than that of the first etching gas.

10. The method of claim 2, wherein forming the preliminary opening and forming the opening comprise applying an oxygen gas and an inactive gas to the insulation layer to control etching ratios of the first etching gas and the second etching gas.

11. The method of claim 10, wherein the first etching gas, the second etching gas, the oxygen gas and the inactive gas are provided in a plasma state.

12. The method of claim 1, wherein the opening has an aspect ratio of more than about 5.

13. A method of forming an opening in a semiconductor device, comprising:
partially etching a layer on a substrate to form a preliminary opening with a protection layer formed on a sidewall of the preliminary opening; and
etching a lower surface of the preliminary opening to form an opening through which a lower layer beneath the layer is exposed.

14. The method of claim 13, wherein the layer is an insulation layer.

15. The method of claim 13, wherein the protection layer includes a polymer having silicon.

16. The method of claim 13, further comprising:
removing the protection layer after forming the opening.

17. The method of claim 13, wherein the preliminary opening is formed using a first etching gas under a silicon-containing gas atmosphere, and the opening is formed using a second etching gas.

18. The method of claim 17, wherein the silicon-containing gas includes at least one selected from the group consisting of tetrafluorosilane (SiF₄), difluorosilane (SiH₂F₂), silyl fluoride (SiH₃F), hexafluorodisilane (Si₂F₆), tetrachlorosilane (SiCl₄), trichlorosilane (SiHCl₃), dichlorosilane (SiH₂Cl₂), monochlorosilane (SiH₃Cl), hexachlorodisilane (Si₂Cl₆) and silane (SiH₄).

19. The method of claim 17, wherein the first etching gas and the second etching gas include chlorine or fluorine.

20. The method of claim 17, wherein the first etching gas is substantially the same as the second etching gas.

21. The method of claim 14, wherein the second etching gas has a higher etching ratio with respect to the insulation layer than that of the first etching gas.

22. The method of claim 17, wherein forming the preliminary opening and forming the opening comprise applying an oxygen gas and an inactive gas to the substrate to control etching ratios of the first etching gas and the second etching gas.

23. The method of claim 22, wherein the first etching gas, the second etching gas, the oxygen gas and the inactive gas are provided in plasma state.

24. The method of claim 13, wherein the opening has an aspect ratio of more than about 5.

25. A method of manufacturing a semiconductor device, comprising:
forming a layer on a semiconductor substrate where an insulation layer having a contact plug is formed;
forming a mask pattern on the layer to selectively expose the layer through the mask pattern;
partially etching the layer using the mask pattern as an etching mask and using a first etching gas including carbon under a silicon-containing gas atmosphere until before the contact plug is exposed to form a preliminary opening;
etching the layer using the mask pattern as an etching mask and using a second etching gas to form an opening through which the contact plug is exposed;
sequentially forming a conductive layer on a sidewall and a bottom face of the opening, and an upper surface of the layer;
selectively etching the conductive layer to form a lower electrode; and
successively forming a dielectric layer and an upper electrode on the lower electrode.

26. The method of claim 25, wherein the layer is a mold layer.

27. A method of manufacturing a semiconductor device, comprising:
forming a layer on a semiconductor substrate where an insulation layer having a contact plug is formed;
partially etching the layer to form a preliminary opening with a protection layer formed on a sidewall of the preliminary opening;
etching a lower surface of the preliminary opening to form an opening through which a lower layer beneath the layer is exposed;
sequentially forming a conductive layer on a sidewall and a bottom face of the opening, and an upper surface of the layer;
selectively etching the conductive layer to form a lower electrode; and
successively forming a dielectric layer and an upper electrode on the lower electrode.

28. The method of claim 28, wherein the layer is a mold layer.

29. The method of claim 28, wherein the lower layer is the contact plug.
